(19) United States
(12) Patent Application Publication
(10) Pub. No.: US 2015/0195949 A1
(43) Pub. Date: Jul. 9, 2015

(54) DX Cooling System for Telecommunication Shelters

(71) Applicant: Mingsheng Liu, Omaha, NE (US)

(72) Inventor: Mingsheng Liu, Omaha, NE (US)

(21) Appl. No.: 14/592,878

(22) Filed: Jan. 8, 2015

Related U.S. Application Data
(60) Provisional application No. 61/924,931, filed on Jan. 8, 2014.

(51) Int. Cl. H05K 7/20; H05K 5/02

(52) U.S. Cl. CPC H05K 7/207; H05K 5/0213; H05K 7/20354; H05K 7/20663

(57) ABSTRACT

A system for and method of controlling the air temperature in a cabinet housing electrical equipment including an air conditioning unit having at least one fan and compressor, at least one supply air temperature sensor and room air temperature sensor. The method comprises providing a speed modulation device operable to control a speed of the at least one compressor, and providing a controller operable to control the speed modulation device and the fan and compressor. The controller controls the speed modulation device and the fan and compressor based on a selection of a plurality of operating modes. The method comprises selecting an initial operating mode, controlling the air conditioning unit based on the selection, determining a relationship between a plurality of temperature parameters, selecting at least one additional operating mode based on the relationship, and controlling the speed modulation device and the fan and compressor based on that additional selection.

### CROSS-REFERENCE TO RELATED APPLICATIONS

This application claims the benefit of U.S. Provisional Patent Application Ser. No. 61/924,931 filed on Jan. 8, 2014.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### TECHNICAL FIELD

The disclosed embodiments generally relate to air conditioning units used in telecommunication shelters and, more particularly, to DX cooling units used in telecommunication shelters.

### DESCRIPTION OF THE RELATED ART

A telecommunications shelter is a small compact space designed to house telecommunications equipment. Controlling the temperature inside these shelters ensures that the housed electronic equipment is maintained in proper working condition. Generally, the shelters must be maintained at an indoor temperature of between 50° F. and 80° F. year round. Small DX units are often used to air-condition telecommunications shelters. Sometimes, two identical units are even installed in the same shelter. Due to the small size of telecommunications shelters and the influence of weather conditions on the load, these air-conditioning units generally vary in weight from a fraction of a ton to up to 5 tons.

Exhaust fans, vortex coolers, Peltier coolers, and passive cooling systems have all been used in the prior art to air condition telecommunications shelters. Various measures have also been taken in the prior art to improve the energy performance of shelter cooling systems. Improvements suggested include such measures as adding an economizer to the cooling unit, installing additions to the refrigeration pump, and introducing natural ventilation. Variable frequency drive technologies have also been attached to unit fan motors in the prior art for the purpose of attaining greater energy savings.

Even with these improvements, however, the compressors of DX-cooling units in the prior art are still configured to run at a constant speed. When at a constant speed, the compressor creates excessive cycling and consumes excess power under lower load conditions. In order to save energy, extend the life of the compressor, and lower costs, it would thus be desirable to operate the compressors of the DX-cooling units at a variable speed.

A novel control system is described in this application that can be integrated with an existing controller to improve the operating performance of a DX cooling unit. Since a variable frequency drive is installed only on the unit compressor, the system refrigeration capacity can be adjusted to a range that is relatively wider than in the prior art. The control system is able to not only simplify room temperature control, but also greatly reduce compressor cycling.

Accordingly, it is one aspect of an embodiment to reduce the amount of energy consumed, improve the system efficiency, and significantly reduce operational and maintenance costs compared with the prior art.

It is another aspect of an embodiment to reduce the on and off cycling of the compressor so as to extend the compressors lifetime.

It is yet a further aspect of an embodiment to implement modulating control to create a smoother room temperature profile.

### SUMMARY OF THE INVENTION

The following summary of the invention is provided to facilitate an understanding of some of the innovative features unique to an embodiment of the present invention and is not intended to be a full description. A full appreciation of the various aspects of the invention can be gained by taking the entire specification, claims, drawings, and abstract as a whole.

In one embodiment, a method of controlling the air temperature in a telecommunications shelter using at least one air conditioning unit including at least one terminal board, at least one fan, at least one compressor, at least one supply air temperature sensor, and a room air temperature sensor associated with the telecommunications center is proposed. The method involves determining a supply air temperature using said supply air temperature sensor and determining a room air temperature using said room air temperature sensor. It also involves providing a speed modulation device configured in communication with and operable to control a speed of said at least one compressor and providing a controller in communication with and operable to control the speed modulation device and the at least one terminal board. The method further entails receiving, by the controller, a fault signal from the speed modulation device. The method further entails inputting into said controller a plurality of temperature control bands and inputting into said controller a temperature set point. The method further entails selecting an initial operating mode. It further entails controlling the speed modulation device and the at least one fan and compressor based on a control logic of the initial operating mode, and determining a relationship between the room air temperature, the temperature set point, and at least one of the plurality of temperature control band parameters. The method further comprises selecting at least one additional operating mode based on the stated relationship and controlling the speed modulation device and the at least one fan and compressor based on the control logic of the stated additional operating mode.

In another embodiment, a system for controlling the temperature of a telecommunications shelter housing at least one air-conditioning unit in communication with a terminal board and including at least one fan, at least one compressor, a supply air temperature sensor operable to determine a supply air temperature, and a room air temperature sensor operable to determine a room air temperature of the shelter is proposed. The control system comprises a speed modulation device configured in communication with and operable to modulate a speed of said at least one compressor and a controller configured in communication with and operable to control the speed modulation device and the terminal board of the at least one air-conditioning unit that activates and deactivates the associated at least one fan and compressor.

The controller of the control system is configured with a plurality of control modes comprising but not limited to an input mode, an off mode, a start-up mode, and a cooling mode. The input mode is configured to input parameters for the controller to read including the room air temperature and the supply air temperature, a fault signal from the speed modulation device, a user selected temperature set point for the at least one air conditioning unit, and a plurality of control band parameters indicative of an accepted temperature variation. In the embodiment, the off module is configured to deactivate the at least one compressor and speed modulation device and to operate the at least one fan at a full speed. The off module is configured to deactivate the fan when a difference between the room air temperature and the supply air temperature is less than a first band of the plurality of control band parameters. When the room temperature is higher than a summation of the room temperature setpoint and a second control band and the air conditioning system is deactivated for a predetermined period of time, the controller switches to the start-up mode. When the room temperature is higher than the summation of the room temperature setpoint and a third control band, the controller switches to the cooling mode. The start-up mode is configured to activate the at least one fan and operate the speed of speed modulation device at a start-up speed. When the start-up time of the controller is less than a predetermined period of time and the room air temperature of the shelter is less than the difference of the room temperature set point and the second control band, the controller switches to the off mode. When the start-up time is greater than a predetermined period of time, the controller switches to the cooling mode. The cooling mode is configured to activate the at least one fan and compressor and to modulate the speed of the modulation device based on the room temperature. When the room temperature is less than the difference between the room temperature set point and the second control band, the controller switches to the off mode.

The above-described features and advantages of the present disclosure thus improve upon aspects of those systems and methods in the prior art designed to calculate for

### BRIEF DESCRIPTION OF THE DRAWINGS

It will be appreciated that for simplicity and clarity of illustration, elements illustrated in the following figures have not necessarily been drawn to scale. For example, the dimensions of some of the elements are exaggerated relative to other elements for clarity. Advantages, features and characteristics of the present disclosure, as well as methods, operation and functions of related elements of structure, and the combination of parts and economies of manufacture, will become apparent upon consideration of the following description and claims with reference to the accompanying drawings, all of which form a part of the specification, wherein like reference numerals designate corresponding parts in the various figures, and wherein:

FIG. 1 is a schematic diagram of the system embodying the principles of a dx cooling unit for telecommunications shelters.

FIG. 2 is a flow chart of the main control logic for the system embodying the principles of a dx cooling unit for telecommunications shelters.

FIG. 3 is a flow chart of the fault mode control logic of the fault mode for the system embodying the principles of a dx cooling unit for telecommunications shelters.

FIG. 4 is a flow chart of the mode control logic of the off mode for the system embodying the principles of a dx cooling unit for telecommunications shelters.

FIG. 5 is a flow chart of the start-up mode control logic for the system embodying the principles of a dx cooling unit for telecommunications shelters.

FIG. 6 is a flow chart of the cooling mode control logic for the system embodying the principles of a dx cooling unit for telecommunications shelters.

### DRAWINGS REFERENCE NUMERALS

100 DX Unit Cooling System
102 Unit 1 Compressor
104 Unit 2 Compressor
106 Unit 1 Fan Motor
108 Unit 2 Fan Motor
110 Supply Air Temperature Sensor
112 Room Air Temperature Sensor
114 Speed Modulation Device
116 Controller
118 Unit 1 Terminal Board
120 Unit 2 Terminal Board
122 Power Source
124 Telecommunications Shelter
200 Main Control Logic
204 Read Inputs
206 Check for Faults
208 Go to Fault Mode
210 Check for Off Mode
212 Go to Off Mode
214 Check for Start-Up Mode
218 Go to Cooling Mode
300 Fault Mode
302 Turn off Spd. Mod. Device, compressors, fan motors
304 Clear Spd. Mod. Device Faults
306 Switch to off Mode
400 Off Mode
402 Command OFF spd. Mod. Device & Compressors
404 If (Tr−Ts)<Band 1, then command the Fan Off
406 If (Tr>Tr,sp+Band 2) and system is off for Time 2, then go to Start-up Mode
408 If (Tr>Tr,sp+Band 3), then go to cooling mode
500 Startup Mode
502 Command fans & compressors on, Spd. Mod. Device at Start-up Speed
504 Go to off mode if StartupTimer<Startup time, and Tᵣ<T_{r,sp}−Band2
506 Go to cooling mode if StartupTimer>Startup time
600 Cooling Mode
602 Command fans, compressors, & Spd. Mod. Device on
604 Go to off mode if Tᵣ<T_{r,sp}-Band 2

### DETAILED DESCRIPTION

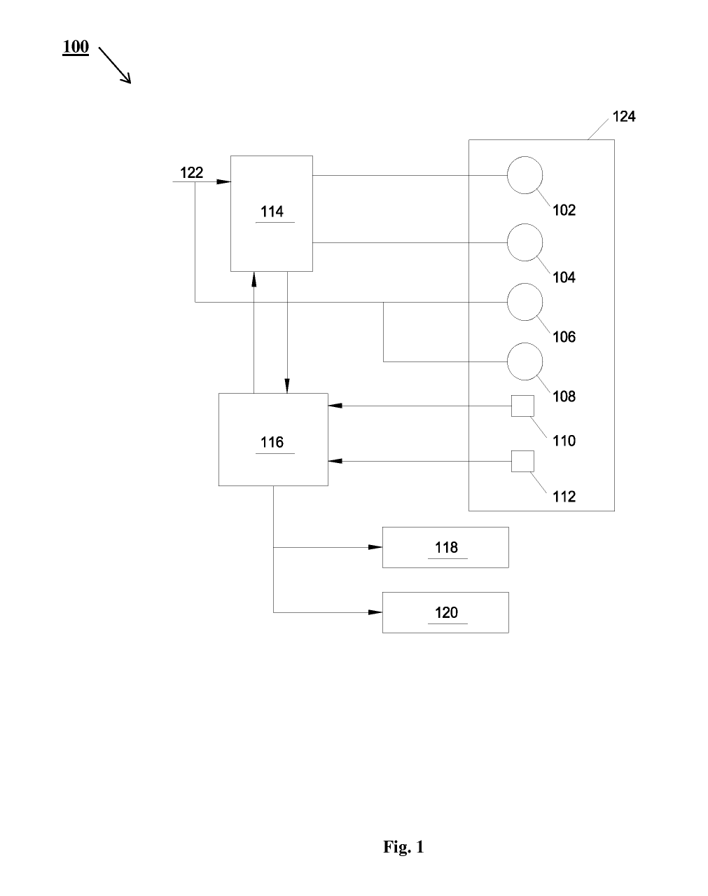

FIG. 1 shown below illustrates an embodiment of DX cooling system 100 for cooling telecommunication shelters. In the figure, system 100 is comprised of unit 1 compressor 102, unit 2 compressor 104, unit 1 fan motor 106, unit 2 fan motor 108, supply air temperature sensor 110, room air temperature sensor 112, speed modulation device 114, controller 116, unit 1 terminal board 118, unit 2 terminal board 120, power source 122, and telecommunications shelter 124. In the illustrated embodiment, controller 116 and speed modulation device 114 are implemented in connection with power source 122, fans 106 and 108, compressors 102 and 104, and temperature sensors 110 and 112 of existing telecommunications shelter 124. They are also installed in connection with terminal boards 118 and 120 to become DX cooling system 100.

When implemented, controller 116 is configured in signal communication with terminal boards 118 and 120, speed modulation device 114, and air temperature sensors 110 and 112. Power source 122 is configured in connection with speed modulation device 114. In some embodiments, power source 122 provides single-phase power, while in other embodiments it provides three-phase power. One of the primary purposes of power source 122 is to power fans 106 and 108 and compressors 102 and 104.

In the illustration, communications shelter 124 is a communications shelter air conditioned by either a single air-conditioning unit or two identical air-conditioning units. However, in other embodiments it can be served by additional or fewer units. In the figure, compressors 102 and 104 and fan motors 106 and 108 are existing compressors and fan motors for each unit. Shelter 124 also houses supply air temperature sensor 110 and room temperature sensor 112. The sensors are configured to measure the supply air temperature and room temperature, respectively, in shelter 124. Unit 1 and unit 2 existing terminal boards 118 and 120 are configured to command the start/stop function of fan motors 106 and 108 as well as that of unit compressors 102 and 104. Fan motors 106 and 108 are kept at a constant speed.

Speed modulation device 114 and controller 116 are configured in connection with the units serving shelter 124 and their (the units) terminal boards 118 and 120. In order to air-condition shelter 124, the supply air temperature of the existing air-conditioning unit as obtained from supply air temperature sensor 110, the room air temperature of shelter 124 collected by room air temperature sensor 112, and the fault signal obtained from speed modulation device 114 are input into controller 116. Based on this input data, controller 116 sends control commands to speed modulation device 114 and unit 1 and 2 terminal boards 118 and 120. Terminal boards 118 and 120 use the commands from controller 116 to start and/or stop the fans and compressors of the units. (In the figure, therefore, unit 1 terminal board 118 commands unit 1 compressor 102 and unit 1 fan motor 106. Likewise, unit 2 terminal board 120 commands unit 2 compressor 104 and unit 2 fan motor 108.)

Speed modulation device 114 is connected to controller 116 and compressors 102 and 104. Device 114 modulates the speed of compressors 102 and 104 to maintain the room temperature. If speed modulation device 114 has faults it sends fault signals to controller 116. Periodically, controller 116 will clear these faults and reset device 114.

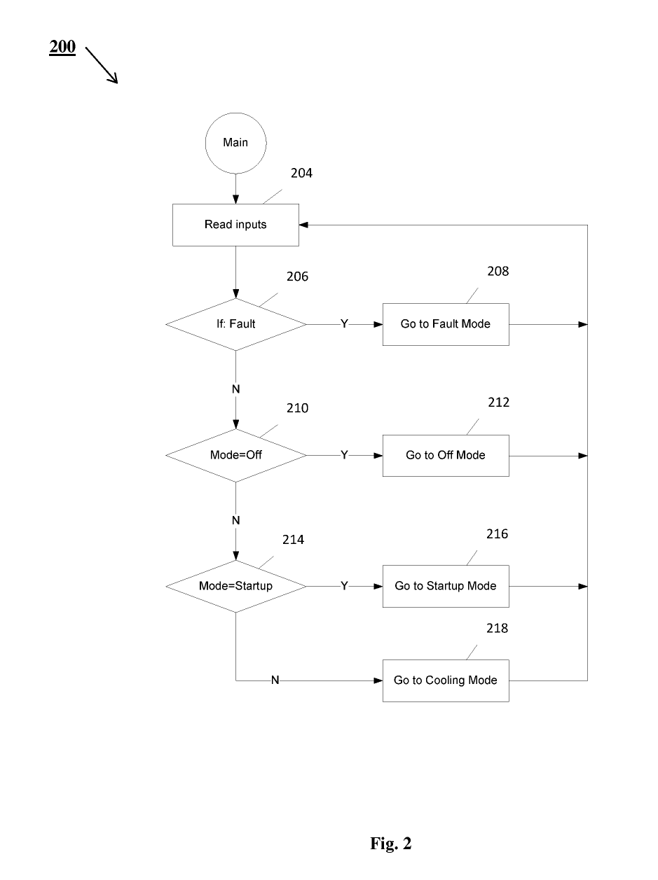

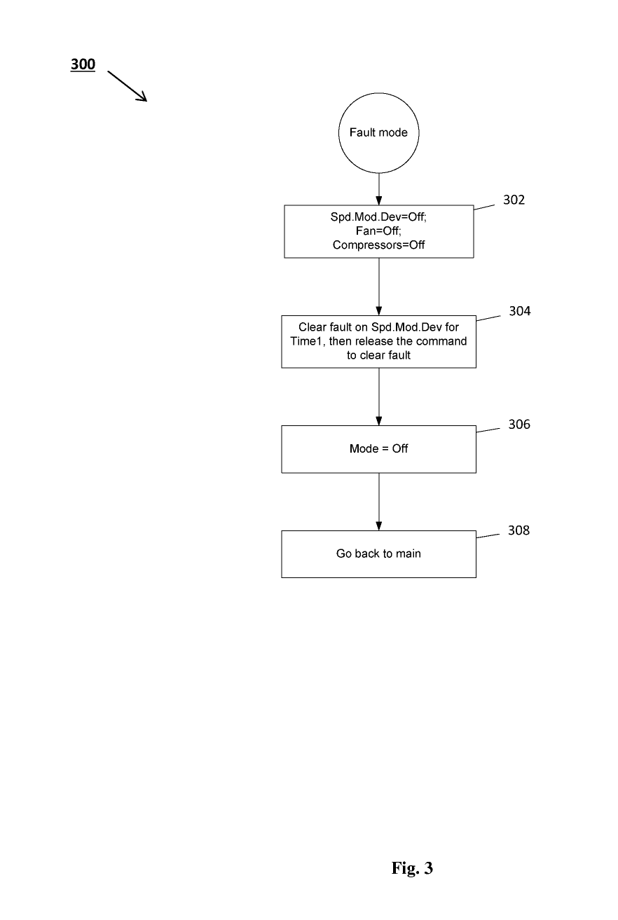

Flow charts describing the control logic of controller 116 are illustrated in FIGS. 2-6. In the described embodiment, controller 116 has four modes: Fault mode, off mode, start-up mode, and cooling mode. FIG. 2 is a flow chart illustrating the general control logic 200 of controller 116. The modes are depicted individually and in more detail in FIGS. 3-6. As depicted in the figure, in a first step 204, controller 116 reads the inputs. If controller 116 finds faults (step 206), it will go to fault mode (step 208). If the controller does not find a fault, it will proceed to check for the off mode in step 210. If the off mode is detected, controller 116 will proceed to off mode in step 212. If controller 116 does not detect the off mode, it will proceed to check for the start-up mode in step 214. If controller 116 detects the start-up mode, it will proceed to the start-up mode in step 216. If it does not detect the start-up mode, controller 116 will proceed to cooling mode in step 218. The previously described control logic continues in a loop.

FIG. 3 is a flow chart illustrating the sequence of the control logic of controller 116 when the controller is in fault mode 300. As shown in the figure, in a first step 302, controller 116 turns off speed modulation device 114, compressors 102 and 104, and fan motors 106 and 108. In a second step 304, the faults for speed modulation device 114 are cleared for a predetermined period of time. Finally, in a third step 306, the system mode is switched to the off mode.

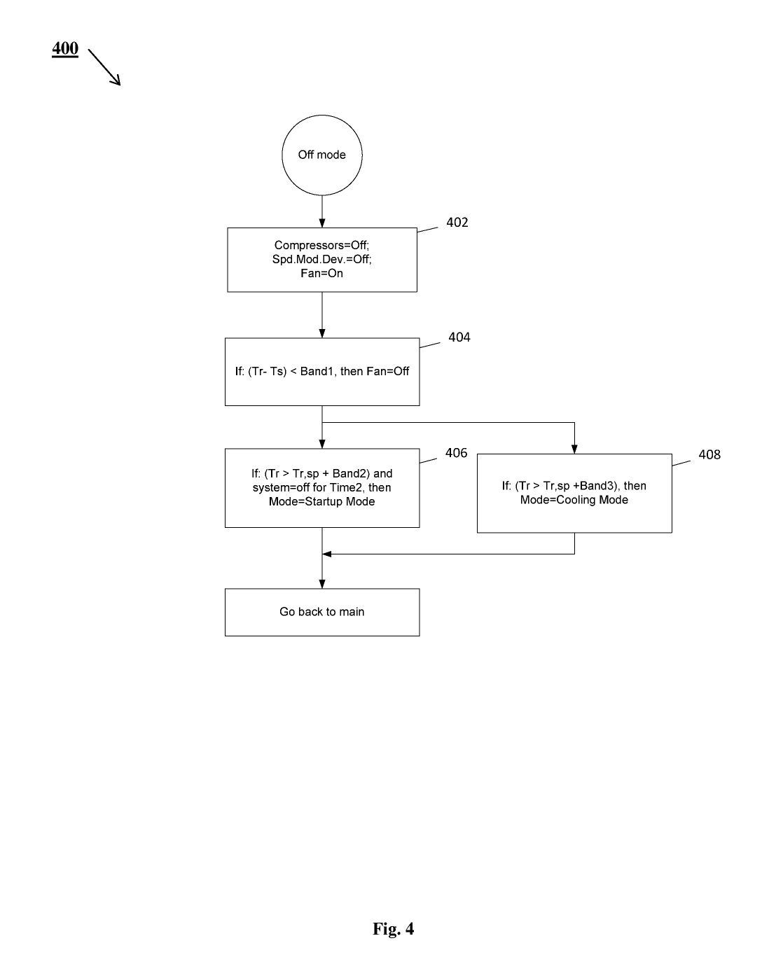

FIG. 4 is a flow chart illustrating the sequence of the control logic of controller 116 when the controller is in off mode 400. As shown in the figure, in a first step 402, controller 116 commands speed modulation device 114 and compressors 102 and 104 off. In this step, controller 116 also runs fan motors 106 and 108 at full speed. In a second step 404, controller 116 commands fan motors 106 and 108 off if the difference between the supply air temperature as measured by supply air temperature sensor 110 and the room temperature as measured by room temperature sensor 112 is lower than a pre-determined band (denoted Band 1). (This band for example may be 5° F. but is not limited to this temperature). In a third step 406, controller 116 proceeds to start-up mode 500 if the room temperature of shelter 124 as measured by room temperature sensor 112 is higher than the room temperature setpoint plus a predetermined band (denoted band 2) and the system is off for a predetermined period of time (this time may for example be 5 minutes but is not limited to this period). In a step 408, controller 116 proceeds to cooling mode 600 if the room temperature is higher than the room temperature setpoint plus a band (denoted Band 3). (The band may for example be 2° F. but is certainly not limited to this temperature).

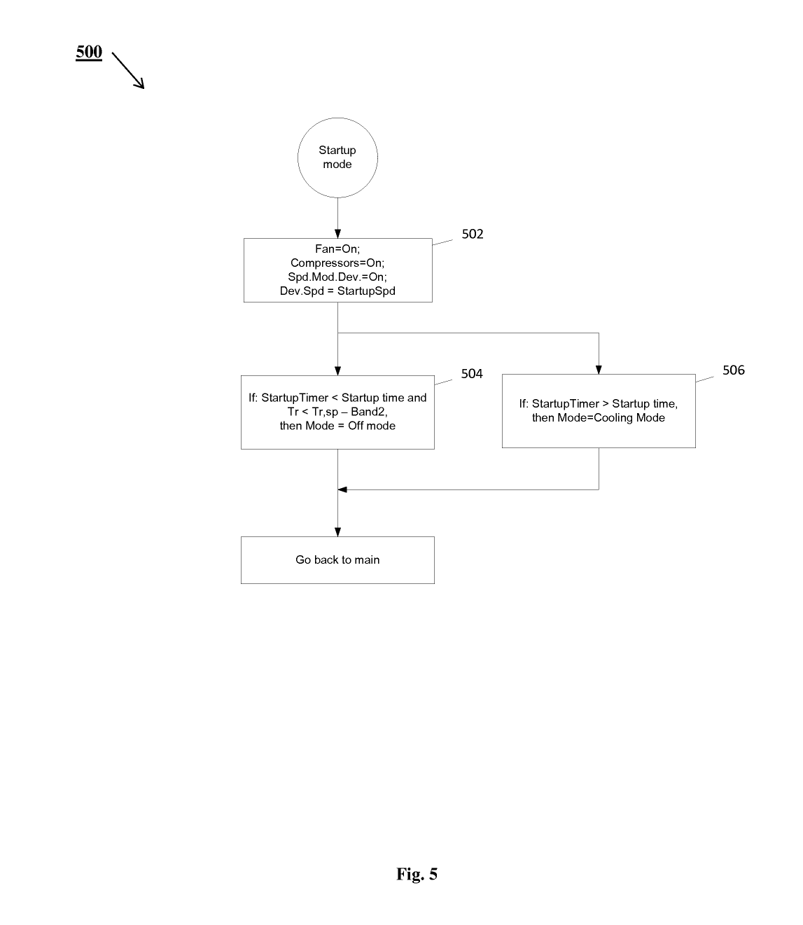

FIG. 5 is a flow chart illustrating the sequence of the control logic of controller 116 when the controller is in start-up mode 500. As shown in the figure, in a first step 502, controller 116 commands on the fan motors 106 and 108. Speed modulation device 114 is commanded on so that it is operating at the start-up speed. In a second step 504, controller 116 proceeds to off mode 400 if the start-up period of controller 116 is less than a predetermined time period (this time may for example be 10 minutes but is not limited to this time) and the room temperature of shelter 124 as measured by room temperature sensor 112 is less than the room temperature set point minus a predetermined band (denoted as band 2). In a third step 506, controller 116 proceeds to cooling mode 600 if the start-up period is greater than a predetermined start-up time.

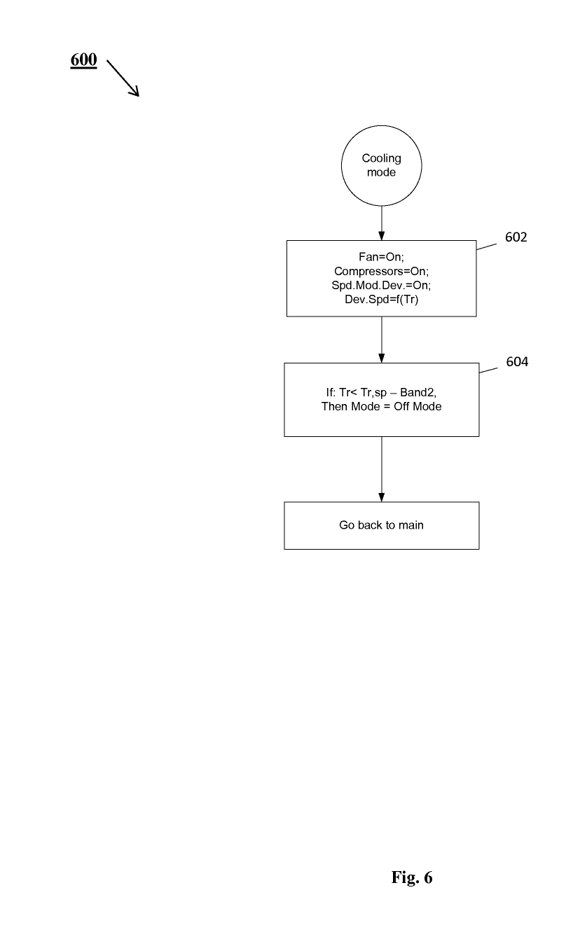

FIG. 6 is a flow chart illustrating the sequence of the control logic of controller 116 when the controller is in cooling mode 600. As shown in the figure, in a first step 602, controller 116 commands on fan motors 106 and 108, compressors 102 and 104, and speed modulation device 114. Device 114 is modulated based on the room temperature of shelter 124 as measured by room temperature sensor 112. In a step 604, controller 116 proceeds to off mode 400 if the room temperature of shelter 124 as measured by room temperature sensor 112 is less than the room temperature set point minus a pre-determined band (denoted as Band 2).

The above-described features and advantages of the present disclosure thus improve upon aspects of those systems and methods in the prior art designed for air conditioning telecommunication shelters.

What is claimed is:

1. A method of controlling the air temperature in a cabinet housing electrical equipment using at least one air conditioning unit including at least one fan and compressor, at least one supply air temperature sensor, and a room air temperature sensor associated with said housing, said method comprising:
determining a supply air temperature using said supply air temperature sensor;
determining a room air temperature using said room air temperature sensor;
providing a speed modulation device configured in communication with and operable to control a speed of said at least one compressor;
providing a controller operating in a plurality of operating modes in communication with and operable to control said speed modulation device and said at least one fan and compressor;
inputting into said controller a timer and predetermined time parameter;
inputting into said controller a plurality of temperature control bands;
inputting into said controller a temperature set point;
selecting, by said controller, an initial operating mode from one of a start-up mode, a cooling mode, and an off mode;
controlling said speed modulation device and said at least one fan and compressor based on said initial operating mode;
determining a relationship between said room air temperature, said temperature set point, and at least one of said plurality of temperature control band parameters;
selecting at least one additional operating mode based on said relationship; and
controlling said speed modulation device and said at least one fan and compressor based on said selecting of said at least one additional operating mode.

2. The method of claim 1, wherein said initial operating mode is said off mode.

3. The method of claim 2, further comprising deactivating said at least one compressor and speed modulation device and operating said at least one fan at full speed,
deactivating said fan when a difference between said room air temperature and said supply air temperature is less than a first band of said plurality of control band parameters;
switching to a start-up mode when said room temperature is higher than a summation of said room temperature setpoint and a second band parameter of said plurality of control band parameters and said system is deactivated for a predetermined period of time;
switching to a cooling mode when said room temperature is higher than the summation of said room temperature setpoint and a third band parameter of said plurality of control band parameters.

4. The method of claim 1, wherein said initial operating mode is said start-up mode.

5. The method of claim 4, further comprising activating said at least one fan and operating said speed modulation device at a start-up speed,
switching, by said controller, to said off mode when a start-up time from said start-up timer is less than said predetermined time parameter and said room air temperature is less than the difference of said room air temperature set point and said second control band parameter of said plurality of control bands, and
switching, by said controller, to said cooling mode when said start-up timer is greater than said predetermined time parameter;

6. The method of claim 1, wherein said initial operating mode is a cooling mode.

7. The method of claim 6, further comprising activating said at least one fan and compressor, and modulating said speed modulation device based on said room temperature,
switching, by said controller, to said off mode when said room temperature is less than a difference between said room temperature set point and said second band parameter of said plurality of control band parameters.

8. The method of claim 1, further comprising inputting into said controller a fault signal from said speed modulation device and determining a fault mode based on said fault signal.

9. A control system configured to control the temperature of a telecommunications shelter housing at least one air-conditioning unit in communication with a terminal board and including at least one fan, at least one compressor, a supply air temperature sensor operable to determine a supply air temperature, and a room air temperature sensor operable to determine a room air temperature of said shelter, said control system comprising:
a speed modulation device configured in communication with and operable to modulate a speed of said at least one compressor;
a controller configured in communication with and operable to control said at least one terminal board and speed modulation device, said controller comprising:
an input module configured to input said room air temperature and said supply air temperature, a fault signal from said speed modulation device, a user selected temperature set point for said at least one air conditioning unit, and a plurality of control band parameters indicative of an accepted temperature variation;
an off module configured to deactivate said at least one compressor and speed modulation device, and operate said at least one fan at full speed and configured to deactivate said fan when a difference between said room air temperature and said supply air temperature is less than a first band of said plurality of control band parameters, switch to a start-up mode when said room temperature is higher than a summation of said room temperature setpoint and a second band parameter of said plurality of control band parameters and said system is deactivated for a predetermined period of time, and switch to a cooling mode when said room temperature is higher than the summation of said room temperature setpoint and a third band parameter of said plurality of band parameters;
a start-up module configured to activate said at least one fan, and operate said speed modulation device at a start-up speed, said module configured to switch to said off module when a start-up speed of said controller is less than a predetermined period of time and said room air temperature is less than the difference of said room temperature set point and said second control band parameter of said plurality of control bands, and switch to said cooling module when said predetermined period of time is greater than a start up time;
a cooling module configured to activate said at least one fan and compressor, modulate said speed modulation device based on said room temperature, and switch to said off module when said room temperature is less than a difference between said room temperature set point and said second band parameter of said plurality of control band parameters.

10. The controller of claim 9, further comprising a fault module configured to determine a fault based on said fault signal.
